(19) United States
(12) Patent Application Publication
(10) Pub. No.: US 2014/0098486 A1
(43) Pub. Date: Apr. 10, 2014

(54) ACTIVE COOLING DOCK FOR COMPUTING DEVICE

(71) Applicant: Steven Davis, Austin, TX (US)

(72) Inventor: Steven Davis, Austin, TX (US)

(21) Appl. No.: 13/646,163

(22) Filed: Oct. 5, 2012

(51) Int. Cl. G06F 1/20; H05K 13/00; G06F 1/16

(52) U.S. Cl. 361/679.41; 29/592.1

(57) ABSTRACT

Various computing devices and methods of thermally managing the same are disclosed. In one aspect, a method of providing air to an interior of a computing device is provided. The method includes docking the computing device to a docking station that includes an air mover operable to deliver air to the interior of the computing device. The docking station is operable to communicate with the computing device to manipulate operation of the air mover in response to cooling requirements of the computing device.

### BACKGROUND OF THE INVENTION

1. Field of the Invention

This invention relates generally to electronic devices, and more particularly to a thermal management system for providing thermal management of portable electronic devices.

2. Description of the Related Art

Handheld computing devices, such as smart phones, tablet computers and e-book readers, present significant thermal management challenges. There is ongoing user demand for devices that are not only smaller form factor for greater portability but also powerful enough to handle video and other computing intensive tasks. The provision for significant computing power in a relatively small form device often translates into the need for significant thermal management of the heat dissipating devices.

One common solution used to transfer heat from a processor in a small form device includes the use of a heat spreader that is in thermal contact with the processor. The heat spreader is in turn, in thermal contact with a heat exchanger via a heat pipe or other structure. The heat exchanger often includes an air mover such as a fan. One example of such a conventional device is the model LE1700 manufactured by Motion Computing, Inc. The LE1700 includes a very thin fan connected thermally to a heat spreader mounted to the microprocessor by way of a heat pipe. The fan vents air to the external ambient by way of a small vent. An Acer model Iconia is another conventional example.

There is an ongoing push to reduce the size, weight and cost of portable computing devices. Weight and form reductions can make portable devices easier to carry, hold and manipulate, and thus improve the user experience. However, there remains user demand for computing performance even if form factors are reduced. To cool such devices, some conventional designs use passive only thermal management. However, passive cooling limits the performance of the platform to the thermal limits of the system. Another conventional solution involves the use of an after-market add-on fan arrangement. The arrangement uses a fan to blow air across the exterior of the computing device. This conventional design cannot move air across a heat dissipating component inside the computing device.

Another potential pitfall associated with the conventional thermal management system just described is the issue of both acoustic and electrical noise associated with a cooling fan. Such issues can be reduced though not completely eliminated through the use of appropriate noise filtering circuitry and fan and vent design. However, there remains the issue of power consumption to run the fan.

The present invention is directed to overcoming or reducing the effects of one or more of the foregoing disadvantages.

### SUMMARY OF EMBODIMENTS OF THE INVENTION

In accordance with one aspect of an embodiment of the present invention, a method of providing air to an interior of a computing device is provided. The method includes docking the computing device to a docking station that includes an air mover operable to deliver air to the interior of the computing device. The docking station is operable to communicate with the computing device to manipulate operation of the air mover in response to cooling requirements of the computing device.

In accordance with another aspect of an embodiment of the present invention, a method of operating a computing device is provided where the computing device includes plural components and an air inlet port and is adapted to operate with or without a docking station. The docking station includes an air mover and an air outlet port adapted to deliver air to the air inlet port of the computing device. The method includes, in an undocked mode, cooling components of the computing device employing only standalone cooling components forming part of the computing device, and, in a docked mode, the computing device sensing a docked status and transmitting control signals to the docking station to control operation of the air mover to deliver from the outlet port to the inlet port modified airflow responsive to the transmitted control signals to cool the components of the computing device.

In accordance with another aspect of an embodiment of the present invention, a method of manufacturing is provided that includes fabricating a docking station operable to dock a computing device that has an interior. The docking station is provided with an air mover operable to deliver air to the interior of the computing device, and is operable to communicate with the computing device to manipulate operation of the air mover in response to cooling requirements of the computing device.

In accordance with another aspect of an embodiment of the present invention, an apparatus is provided that includes a docking station operable to dock a computing device that has an interior. The docking station includes an air mover operable to deliver air to the interior of the computing device and is operable to communicate with the computing device to manipulate operation of the air mover in response to cooling requirements of the computing device.

In accordance with another aspect of an embodiment of the present invention, a computing system is provided that includes a computing device that has an interior and is adapted to dock to the docking station so that the interior receives air from the air mover. The computing device is operable to communicate with the docking station to manipulate operation of the air mover in response to cooling requirements of the computing device.

### BRIEF DESCRIPTION OF THE DRAWINGS

The foregoing and other advantages of the invention will become apparent upon reading the following detailed description and upon reference to the drawings in which:

FIG. 1 is a schematic view of an exemplary embodiment of a computing system that includes a computing device and a docking station;

FIG. 2 is a pictorial view of an exemplary embodiment of a computing system that includes a computing device and a docking station;

FIG. 3 is a sectional view of portions of the exemplary computing device and docking station depicted in FIG. 2;

FIG. 4 is a pictorial view of an alternate exemplary embodiment of a computing system that includes a computing device and a docking station; and

FIG. 5 is a flow chart illustrating an exemplary method of providing air to a computing device with a docking station.

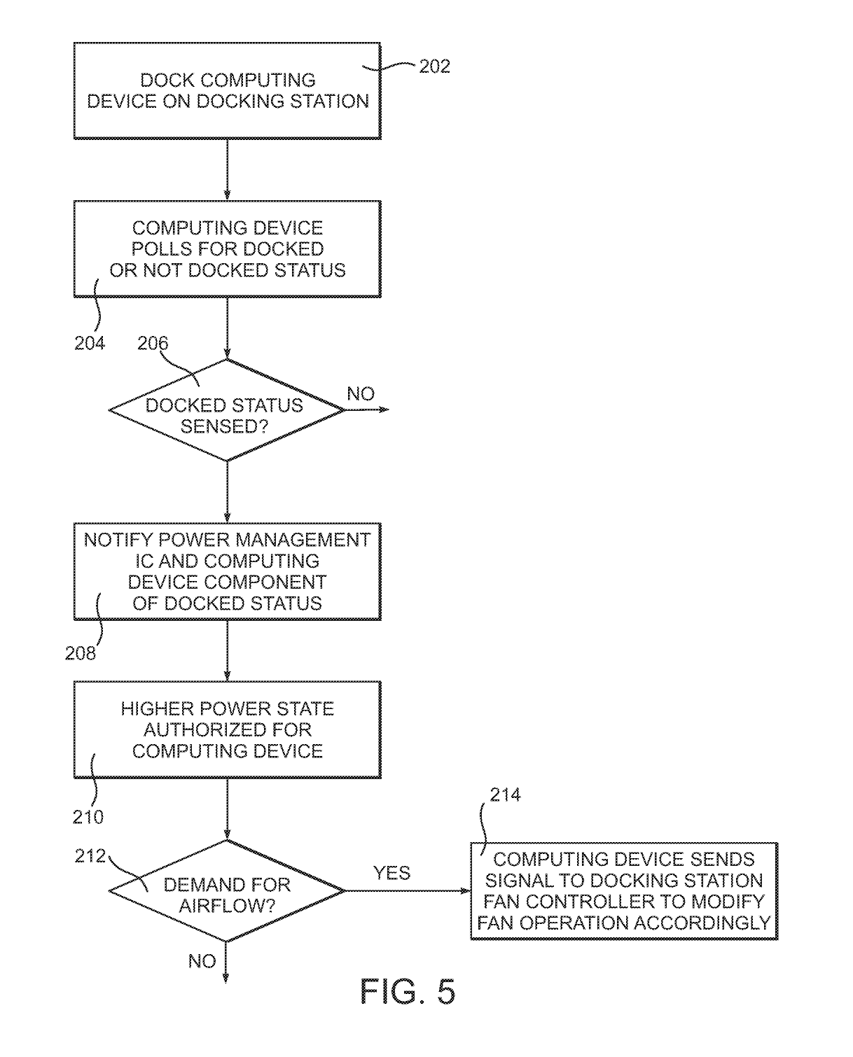

### DETAILED DESCRIPTION OF SPECIFIC EMBODIMENTS

Various embodiments of a computing system are disclosed. In one arrangement, a computing device, such as a tablet computer, may be paired with a docking station that includes an air mover. The computing device and the docking station include cooperating air ports to enable the air mover to deliver cooling air to the interior of the computing device. The computing device can communicate with a fan controller in the docking station to tailor air flow to heat generation. Additional details will now be described.

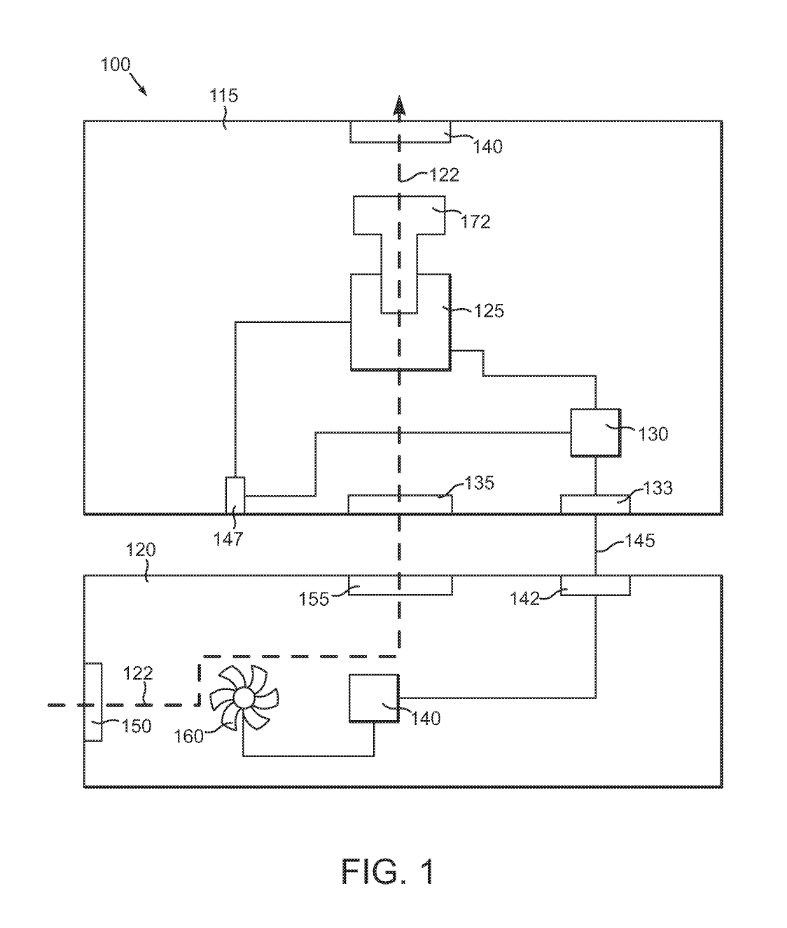

In the drawings described below, reference numerals are generally repeated where identical elements appear in more than one figure. Turning now to the drawings, and in particular to FIG. 1, which is a schematic view of an exemplary embodiment of a computing system 100 that includes a computing device 115 and a docking station 120. The docking station 120 is operable to supply cooling air, and optionally user inputs, power and data, to the computing device 115. In FIG. 1, the computing device 115 is shown docked to the docking station 120. The computing device 115 may be any of a great variety of different types of computing devices, such as tablet computers, notebook computers, netbook computers, smart phones, point of sale machines or others to name just a few. The computing device 115 includes at least one internal component 125 that may benefit from active cooling. The component 125 may be an integrated circuit, a circuit board or virtually any other type of device that may benefit from thermal management by way of air flow. Examples of integrated circuits include processors, such as microprocessors, graphics processors, combined microprocessor/graphic processors, memory devices, communications devices or others. The computing device 115 may further include a power management integrated circuit (IC) 130 that is operable, among other things, to coordinate with one or more components in the docking station 120 as described in more detail below. The computing device 115 is operable to receive cooling air 122 from the docking station 120. However, the computing device 115 may include stand alone passive and/or active cooling as well.

The computing device 115 includes an input/output (I/O) port 133 connected to the power management IC 130. The I/O port 133 may be a male/female pin port, USB port or connector, a wireless port, such as infrared or near field communication (NFC), or other types of ports. The computing device 115 further includes an air inlet port 135 and an optional air outlet port 140.

The docking station 120 includes an 1/O port 142 operable to establish a connection 145 with the I/O port 133 of the computing device 115. The I/O port 142 may be a male/female pin port, USB port or connector, a wireless port, such as infrared or NFC, or other types of ports. Thus, the connection 145 may be wired or wireless. Cabling may be used as necessary to electrically connect the ports 133 and 142.

The docking station 120 further includes an air inlet port 150 and an air outlet port 155. To facilitate movement of the air 122, the docking station 120 is provided with at least one fan 160 and a fan controller 165 connected to the fan 160. The fan 160 may be a low profile centrifugal fan, an axial flow fan or virtually any other type of air movement device. The fan controller 165 may be an integrated circuit operable to not only manage the operation of the cooling fan 150, but also to communicate with the power management IC 130 of the computing device 115 by way of the I/O ports 133 and 142 and the connection 145. The mere establishment of the connection 145 may be sufficient to notify the component that the computing device 115 is docked to the docking station. However, this notification function can be provided or augmented by incorporating a sensor(s) 147 into the computing device 115 that is operable to sense docking and notify both the component 125 and the power management IC 130. The sensor 147 may be an NFC device or other type of sensor.

Air 122 is drawn in through the inlet port 150 by way of the fan 160 and delivered to the air outlet 155. Since the computing device 115 is held in close proximity to the docking station 120, particularly so that the air inlet port 135 is in close proximity and alignment with the air outlet port 155 of the docking station 120, the air 122 may flow readily through the air inlet port 135 into the interior of the computing device 115 to provide cooling of the component 125. Ultimately, the air 122 may exit the air outlet port 165 of the computing device 15. If desired, the computing device 115 may include a heat spreader 172 in thermal contact with the component. The heat spreader 172 may be constructed of well-known thermally conductive materials, such as copper, aluminum, stainless steel or others. The cooling air 122 may be blown past the heat spreader 122.

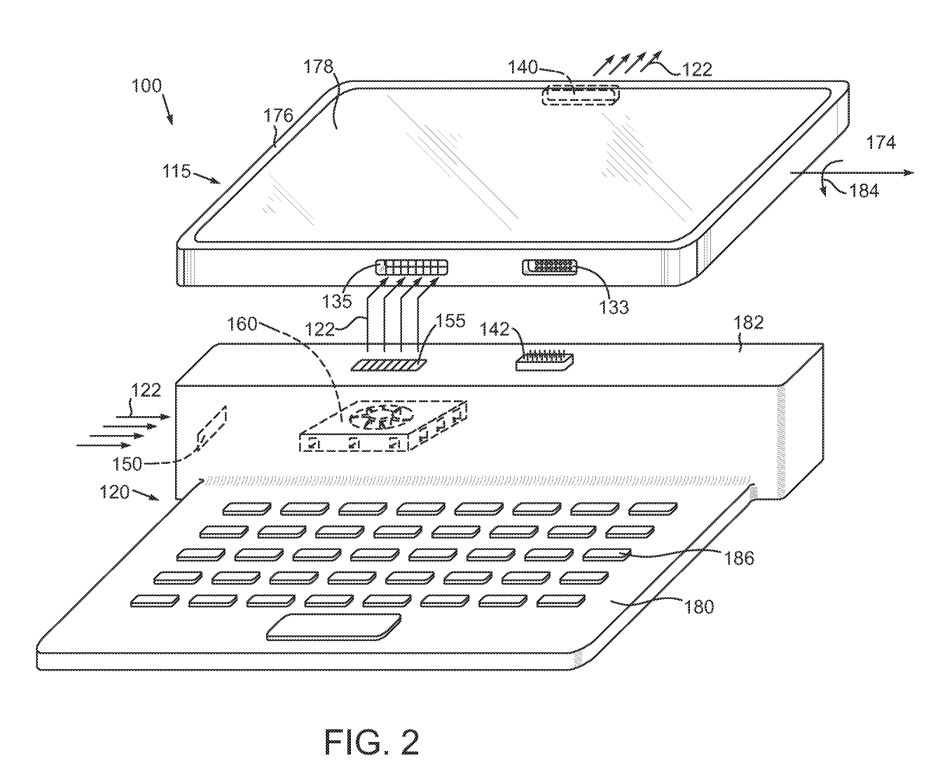

The computing system 100 depicted schematically in FIG. 1 may take on a large number of different configurations. One such exemplary embodiment of the computing system 100 is depicted pictorially in FIG. 2. Here, the computing device 115 may be a tablet computer dockable with the docking station 120. Note that the computing device 115 is shown rotated about the axis 174 from an upright or docked position, which reveals the I/O port 133 and the air inlet port 135, but obscures the air outlet port 140 (shown in dashed). The skilled artisan will appreciate that a tablet computer may take on a great variety of different physical configurations. Here, the computing device 115 configured as a tablet computer may include a peripheral bezel 176 composed of various metals, plastics or combinations of the two and a display screen 178 that may or may not be touch enabled. The air inlet port 135 projects through the bezel 176 and the I/O port 133 is positioned at the bezel 176 as well. In addition, the optional air outlet port 140 leads through the bezel 176 as shown.

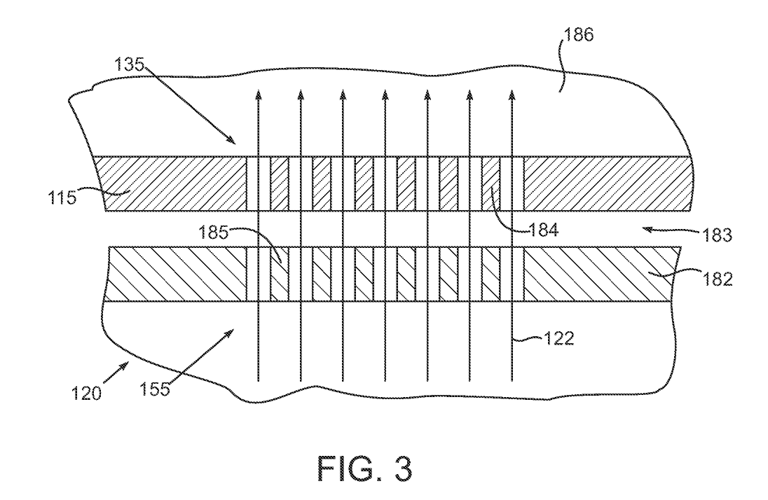

The docking station 120 may similarly take on a variety of configurations. In this embodiment, the docking station 120 may include an external keypad 180 that is connected to or integral with a housing 182, which contains the cooling fan 160. The docking station 120 and in particular the keypad 180 may include plural user input keys 186 as shown, and may include a variety of other peripheral devices and ports such as disk drives, mice, USB ports, video ports, or virtually any other type of port. The docking station 120 may be composed of well-known metals, plastics, combinations of the two or the like. In addition, the housing 182 may include the aforementioned air inlet port 150, the air outlet port 155 and the I/O port 142. Thus, when the computing device 115 is rotated about the axis 174 in the direction of the arrow 184 and seated on the housing 182, the I/O ports 133 and 142 will cooperatively engage and the inlet port 135 of the computing device and the outlet port 155 of the docking station 120 will line up in close proximity so that air 122 taken in through the inlet port 150 of the docking station 120 will be moved by the fan 160 out the exhaust port 155 and into the inlet port 135 of the computing device 115 and ultimately exhaust from the exhaust port 140. FIG. 3 is a sectional view of small portions of the computing device 115 and the housing 182 of the docking station 120 in docked mode. Note that the air inlet port 135 of the computing device 115 and the air outlet port 155 of the docking station 120 are aligned but separated by a small gap 183, which may be very small. The air inlet port 135 and the air outlet port 155 may include grids 184 and 185, respectively, to discourage entry of foreign objects. Air 122 is delivered to the interior 186 of the computing device 115. Here, the air ports 135, 140, 150 and 155 may be gridded and rectangular, but many other shapes and configurations are envisioned. As noted above, the fan 160 may be a low profile centrifugal fan as depicted or an axial flow fan or virtually any other type of air mover. Various ducts (not shown) may link the inlet port 150, the fan 160 and the outlet port 155.

In the embodiment of the computing device 100 depicted in FIGS. 2 and 3, the air 122 flows from the exhaust port 155 of the docking station 120 across a small gap 183 and into the inlet port 135 of the computing device 115. However, it may be possible to fabricate cooperative ducting to enable air to flow directly from the docking station 120 into the interior of a computing device. For example, and as depicted in FIG. 3, an alternative computing system 100′ may include a computing device 115′ and docking station 120′ that, when docked, form a cooperative ducting arrangement for the movement of the air 122. Note, the computing device 115′ and the docking station 120′ may be substantially identical to the computing device 115 and the docking station 120 depicted and described above with a few notable exceptions. In this regard, the air outlet port 155′ of the housing 182′ of the docking station 120′ may include a male duct connector 188 that is operable to be inserted into an alterative air inlet duct 135′. In this way, when the computing device 115′ is seated on the docking station 120′, the duct connector 188 will project up into the port 135′ and provide a direct flow path for the air 122. Like the other illustrative embodiment depicted and described above, the air 122 is taken into the air inlet 150 of the housing 182′, moved by the cooling fan 160 through the duct connector 188 and, via the port 135′, delivered through the computing device 115′ and ultimately and optionally exhausted out of the optional exhaust port 140. Various ducts (not shown) may link the inlet port 150, the fan 160 and the outlet port 155′. As with the other illustrative embodiment, the computing device 115′ includes the I/O port 133 that is operable to cooperate with the I/O port 142 of the docking station 120′. It may also be possible to fit the inlet port 135′ with a removable hatch 190 to prevent foreign materials from entering the interior of the computing device 115′. The hatch 190 may be placed in the port 135′ when the computing device 115′ is not docked on the docking station 120′.

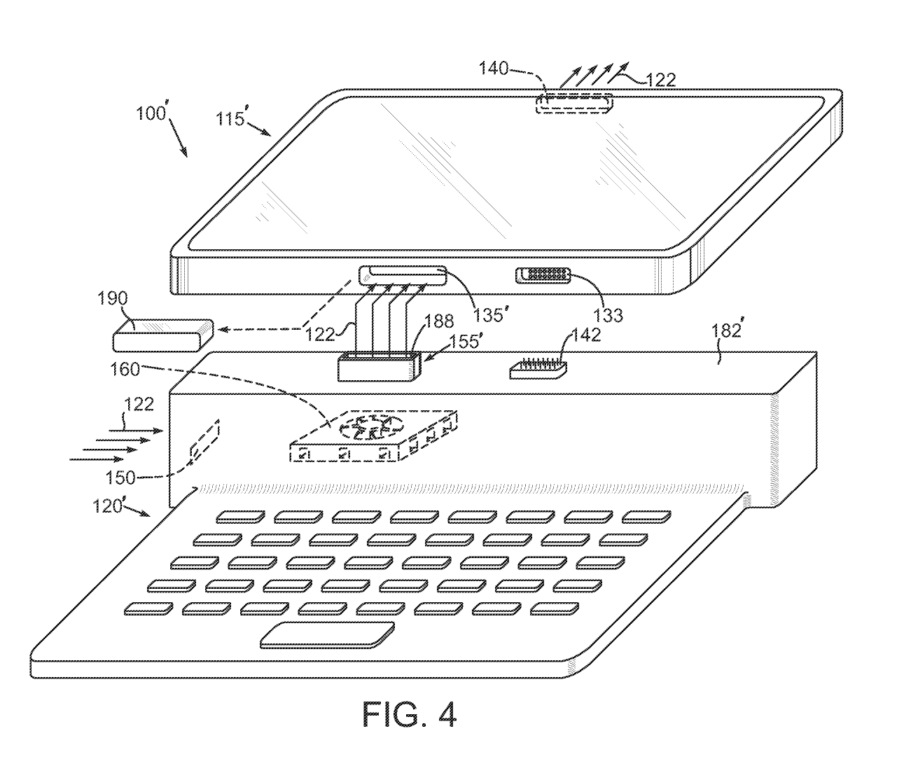

FIG. 4 is a flow chart of an exemplary method of providing cooling air to a computing device of any of the disclosed embodiments of a computing system. At step 202, the computing device is docked on the docking station. This will entail, for example, docking any of the disclosed embodiments of the computing device 115, 115′, etc. on the docking station 120, 120′, etc. At step 204, the computing device polls for docking status, i.e. docked or not docked. This may entail, for example, the component 125 depicted in FIG. 1 sensing the connection 145 and/or the sensor 147 providing an indication of docked or not docked status. Step 206 is a conditional. If a docked status is sensed at step 206, then the power management IC and the computing device component are notified of the docked status at step 208. If the docked status sensed is “NO” at step 206, then either the polling is continued or an alarm may be triggered to indicate anon-docked status for the user. At step 210, a higher power state is authorized for the computing device based on the notification of the docked status at step 208. Step 212 is a conditional. If the computing device requires airflow, i.e. a “YES”, the computing device sends a signal to the docking station fan controller to modify fan operation accordingly at step 214. This may entail turning the fan on, speeding it up or slowing it down. The algorithm used to modify the behavior of the fan may be based on pulse width modulation or other types of fan control algorithms.

Referring again to FIG. 1, It should be understood that the disclosed embodiments of the computing device 115 and docking station 120 (and any disclosed alternatives) can be used to provide thermal management for versions of the component 125 manufactured with different thermal design powers (TDP). Assume for the purposes of illustration that the component 124 is a processor. One version of the component 125 may have some TDP with a value of X, another version may have a TDP with a value of 0.8X, and another version with a TDP of 0.7X and so on. The docking station 120 may provide air flow to a computing device 115 fitted with a component at each TDP by modifying the air mover control algorithm accordingly.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A method of providing air to an interior of a computing device, comprising:
docking the computing device to a docking station, the docking station including an air mover operable to deliver air to the interior of the computing device and being operable to communicate with the computing device to manipulate operation of the air mover in response to cooling requirements of the computing device.

2. The method of claim 1, wherein the computing device includes an air inlet port and the docking station includes an air outlet port operable to deliver the air to the air inlet port.

3. The method of claim 2, wherein the air inlet port and the air outlet port are substantially aligned.

4. The method of claim 2, wherein the air outlet port includes a male duct connector, the method comprising inserting the male duct connector into the air inlet port.

5. The method of claim 1, wherein the docking station includes a first I/O port and the computing device includes a second I/O port engageable with the first I/O port, the method comprising establishing a connection between the first and second I/O ports.

6. The method of claim 2, comprising exhausting air from an exhaust port of the computing device.

7. The method of claim 1, comprising controlling operation of the air mover by signals from the computing device.

8. A method of operating a computing device, the computing device including plural components and an air inlet port and being adapted to operate with or without a docking station, the docking station including an air mover and an air outlet port adapted to deliver air to the air inlet port of the computing device, comprising:
in an undocked mode, cooling components of the computing device employing only standalone cooling components forming part of the computing device; and
in a docked mode the computing device sensing a docked status and transmitting control signals to the docking station to control operation of the air mover to deliver from the outlet port to the inlet port modified airflow responsive to the transmitted control signals to cool the components of the computing device.

9. A method of manufacturing, comprising:
fabricating a docking station operable to dock a computing device having an interior; and
providing the docking station with an air mover operable to deliver air to the interior of the computing device, the docking station being operable to communicate with the computing device to manipulate operation of the air mover in response to cooling requirements of the computing device.

10. An apparatus, comprising:
a docking station operable to dock a computing device having an interior; and
the docking station including an air mover operable to deliver air to the interior of the computing device, and being operable to communicate with the computing device to manipulate operation of the air mover in response to cooling requirements of the computing device.

11. The apparatus of claim 10, comprising the computing device coupled to the docking station, the computing device including an air inlet port, the docking station including an air outlet port operable to deliver the air to the air inlet port.

12. The apparatus of claim 11, wherein the air inlet port and the air outlet port are substantially aligned.

13. The apparatus of claim 11, wherein the air outlet port includes a male duct connector operable to be inserted into the air inlet port.

14. The apparatus of claim 11, wherein the docking station includes a first I/O port and the computing device includes a second I/O port engageable with the first I/O port when the computing device is docked to the docking station.

15. The apparatus of claim 11, wherein the computing device includes an air exhaust port.

16. The apparatus of claim 11, wherein the air mover is controllable by signals from the computing device.

17. A computing system, comprising:
a computing device having an interior and being adapted to dock to a docking station having an air mover and so that the interior receives air from the air mover, the computing device being operable to communicate with the docking station to manipulate operation of the air mover in response to cooling requirements of the computing device.

18. The computing system of claim 17, comprising the docking station including the air mover.

19. The computing system of claim 18, wherein the computing device includes an air inlet port and the docking station includes an air outlet port operable to deliver the air to the air inlet port.

20. The computing system of claim 19, wherein the air inlet port and the air outlet port are substantially aligned when the computing device is docked on the docking station.

21. The computing system of claim 19, wherein the air outlet port includes a male duct connector operable to be inserted into the air inlet port.

22. The computing system of claim 18, wherein the docking station includes a first I/O port and the computing device includes a second 1/O port engageable with the first I/O port when the computing device is docked to the docking station.

23. The computing system of claim 17, wherein the computing device includes an air exhaust port.

24. The computing system of claim 17, wherein the air mover is controllable by signals from the computing device.
